(19) United States
(12) Patent Application Publication
(10) Pub. No.: US 2026/0089834 A1
(43) Pub. Date: Mar. 26, 2026

(54) RESIN LAMINATED BOARD AND METHOD FOR MANUFACTURING RESIN LAMINATED BOARD

(71) Applicant: Murata Manufacturing Co., Ltd., Nagaokakyo-shi (JP)

(72) Inventors: Shohei SAKAI, Nagaokakyo-shi (JP); Kosuke NISHIO, Nagaokakyo-shi (JP)

(21) Appl. No.: 19/407,811

(22) Filed: Dec. 3, 2025

Related U.S. Application Data
(63) Continuation of application No. PCT/JP2024/020154, filed on Jun. 3, 2024.

(30) Foreign Application Priority Data
Jul. 25, 2023 (JP) 2023-120566

(51) Int. Cl. H05K 1/02; H05K 1/03; H05K 1/11; H05K 1/185; H05K 3/46

(52) U.S. Cl. CPC H05K 1/024; H05K 1/036; H05K 1/115; H05K 1/185; H05K 3/4632; H05K 2201/0129; H05K 2201/0195; H05K 2201/093; H05K 2201/10098

(57) ABSTRACT

A resin laminated board includes resin layers laminated on one another and conductors located outside and inside the laminated resin layers. The resin layers include a first resin layer, a second resin layer, and a third resin layer sequentially laminated on one another. The conductors include first conductor layers, second conductor layers, and interlayer connection conductors. The first conductor layers are located at a lower main surface of the first resin layer. The second conductor layers or the interlayer connection conductors that overlap a portion of the first resin layer when viewed in a thickness direction of the third resin layer are located at the third resin layer. The second resin layer is a thermoplastic resin, and a melting point of the second resin layer is lower than a melting point of the first resin layer. At least the second resin layer includes air bubbles.

### CROSS REFERENCE TO RELATED APPLICATIONS

This application claims the benefit of priority to Japanese Patent Application No. 2023-120566 filed on Jul. 25, 2023 and is a Continuation Application of PCT Application No. PCT/JP2024/020154 filed on Jun. 3, 2024. The entire contents of each application are hereby incorporated herein by reference.

### BACKGROUND OF THE INVENTION

### 1. Field of the Invention

The present invention relates to resin laminated boards each including multiple resin layers laminated on one another to define a portion of a laminated body, and conductor layers located outside and inside the laminated body, and methods for manufacturing the resin laminated boards.

### 2. Description of the Related Art

For example, Japanese Patent No. 5927946 discloses a method for manufacturing a multilayer wiring board including a process of thermocompression bonding performed on laminated multiple resin sheets with integrated multilayer pressing, and a multilayer wiring board manufactured by such a method.

The multilayer wiring board described in Japanese Patent No. 5927946 includes multiple wiring boards that are connected to each other with inner vias. The method for manufacturing this multilayer board includes a process of forming a conductor pattern defining and functioning as a wiring board on the surface of a thermoplastic resin sheet, a process of positioning a laminated body formed by laminating multiple resin sheets between a first pressing plate and a second pressing plate, and placing, between the laminated body and at least one of the first pressing plate and the second pressing plate, a compressive cushion sheet including a graphite sheet obtained by compressing expanded graphite, and a process of pressing the laminated body between the first pressing plate and the second pressing plate in the lamination direction while heating the laminated body.

### SUMMARY OF THE INVENTION

With the method for manufacturing a multilayer wiring board described in Japanese Patent No. 5927946, the arrangement of the interlayer connection conductors and the ratio of remaining copper in each layer vary, and thus, the coplanarity of the resin layer surface and the copper foil surface (substrate surface) of the pressed multilayer wiring board is lowered.

Example embodiments of the present invention provide resin laminated boards each including a surface with improved coplanarity, and methods for manufacturing the resin laminated boards.

(1) A resin laminated board according to an example of the present disclosure includes a plurality of resin layers laminated on one another, and conductors located inside and outside the laminated plurality of resin layers, wherein the plurality of resin layers include a first resin layer, a second resin layer, and a third resin layer sequentially laminated on one another, the conductors include a first conductor layer, a second conductor layer, and an interlayer connection conductor, the first resin layer includes an upper main surface and a lower main surface opposite to each other, the second resin layer has an upper main surface and a lower main surface opposite to each other, the upper main surface of the first resin layer is in contact with the lower main surface of the second resin layer, the first conductor layer is located at the lower main surface of the first resin layer, the second conductor layer or the interlayer connection conductor that overlaps a portion of the first conductor layer when viewed in a thickness direction of the third resin layer is located at the third resin layer, the second resin layer is a thermoplastic resin, and a melting point of the second resin layer is lower than a melting point of the first resin layer, and at least the second resin layer includes air bubbles.

(2) A method for manufacturing a resin laminated board according to an example embodiment of the present disclosure includes performing thermal pressing at a temperature higher than a melting point of the second resin layer, and lower than a melting point of the first resin layer.

According to example embodiments of the present invention, resin laminated boards each including a surface with improved coplanarity are provided.

The above and other elements, features, steps, characteristics and advantages of the present invention will become more apparent from the following detailed description of the example embodiments with reference to the attached drawings.

### BRIEF DESCRIPTION OF THE DRAWINGS

FIG. 1 is a cross-sectional view of a structure of each resin layer forming a portion of the resin laminated board according to the first example embodiment of the present invention.

FIG. 2 is a cross-sectional view of a resin laminated board 1 formed by thermal pressing.

FIG. 3 is a cross-sectional view of a resin laminated board 1A according to the first example embodiment, different from the resin laminated board illustrated in FIG. 2.

FIG. 4 is a cross-sectional view of a structure of each resin layer forming a portion of a resin laminated board according to a second example embodiment of the present invention.

FIG. 5 is a cross-sectional view of a structure of each resin layer forming a portion of a resin laminated board according to a third example embodiment of the present invention.

FIG. 6 is a cross-sectional view of a resin laminated board 3 formed by thermal pressing.

FIG. 7 is a cross-sectional view of a structure of each resin layer forming a portion of a resin laminated board according to a fourth example embodiment of the present invention.

FIG. 8 is a cross-sectional view of a resin laminated board 4 formed by laminating the resin layers illustrated in FIG. 7, and by thermally pressing the resin layers with a rigid structure.

FIG. 9 is a cross-sectional view of a resin laminated board 4A according to the fourth example embodiment, different from the resin laminated board 4 illustrated in FIG. 8.

FIG. 10 is a perspective view of a structure of each resin layer forming a portion of a resin laminated board according to a fifth example embodiment of the present invention.

FIG. 11 is a cross-sectional view of a structure of each resin layer forming a portion of the resin laminated board according to the fifth example embodiment of the present invention.

FIG. 12 is a cross-sectional view of a resin laminated board 5 formed by laminating the resin layers illustrated in FIG. 11, and thermally pressing the resin layers with a rigid structure.

FIG. 13 is a cross-sectional view of a resin laminated board 5A according to the fifth example embodiment, different from the resin laminated board illustrated in FIG. 12.

### DETAILED DESCRIPTION OF THE EXAMPLE EMBODIMENTS

With reference to the drawings, several specific examples are provided below to describe multiple example embodiments for embodying the present invention. In each of the drawings, the same reference numerals denote the same components. For describing the related points and facilitating understanding, the present invention is described in multiple example embodiments for convenience of description, but components in different example embodiments may be partially replaced or combined with each other. In the description of the second example embodiment and subsequent example embodiments, matters common to the first example embodiment are omitted, and only the differences are described. In particular, similar structures having similar functions and effects are not repeatedly described for each example embodiment.

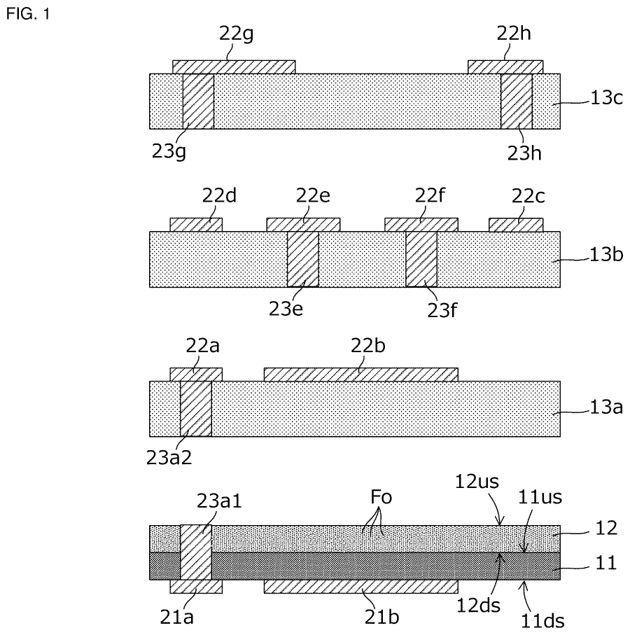

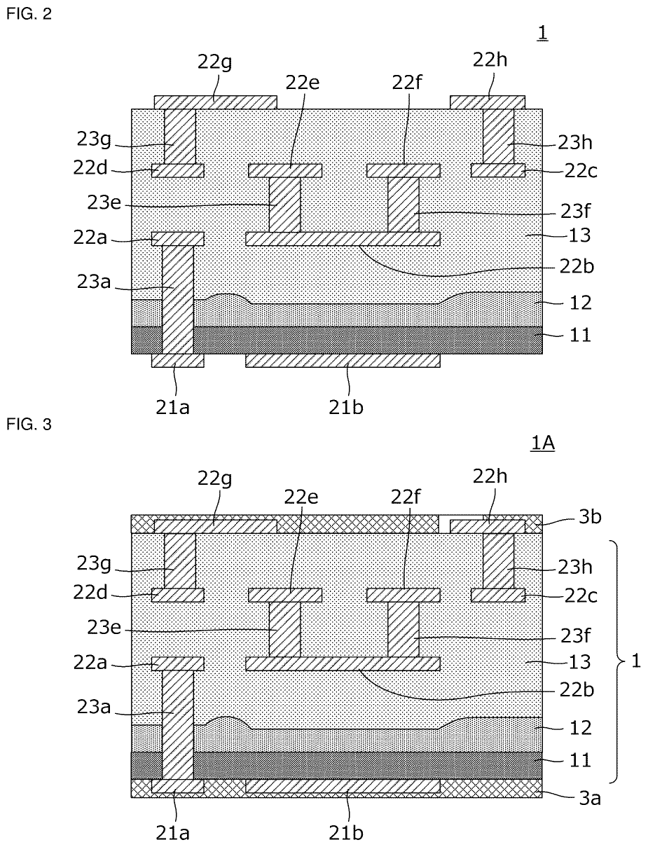

FIG. 1 is a cross-sectional view of a structure of each resin layer forming a portion of a resin laminated board according to a first example embodiment. FIG. 2 is a cross-sectional view of a resin laminated board 1 formed by thermal pressing.

The resin laminated board 1 includes multiple resin layers laminated on one another, and conductors located outside and inside the laminated multiple resin layers. In FIG. 1 and FIG. 2, a first resin layer 11, a second resin layer 12, and third resin layers 13a, 13b, and 13c correspond to resin layers described above. First conductor layers 21a and 21b, second conductor layers 22a to 22h, and interlayer connection conductors 23a1, 23a2, 23e, 23f, 23g, and 23h correspond to conductors described above.

The first resin layer 11, the second resin layer 12, and the third resin layers 13a, 13b, and 13c all include, for example, liquid crystal polymer (LCP), polytetrafluoroethylene (PTFE), or polyimide (PI), but have different melting points. At least the second resin layer 12 includes a thermoplastic resin.

As illustrated in FIG. 1, the first resin layer 11 includes an upper main surface 11us and a lower main surface 11ds opposite to each other. The second resin layer 12 includes an upper main surface 12us and a lower main surface 12ds opposite to each other.

The upper main surface 11us of the first resin layer 11 is in contact with the lower main surface 12ds of the second resin layer 12. More specifically, the first resin layer 11 and the second resin layer 12 are in direct contact with each other, and no conductor layer is located between the first resin layer 11 and the second resin layer 12.

The first conductor layers 21a and 21b are located at the lower main surface 11ds of the first resin layer 11.

The interlayer connection conductor 23a2 and the second conductor layer 22a overlapping the first conductor layer 21a when viewed in the thickness direction of the third resin layer 13a are located at the third resin layer 13a. In addition, the second conductor layer 22b is located at the third resin layer 13a.

The interlayer connection conductors 23e and 23f and the second conductor layers 22e and 22f that overlap the second conductor layer 22b when viewed in the thickness direction of the third resin layer 13b are located at the third resin layer 13b. The second conductor layers 22c and 22d are also located at the third resin layer 13b.

The interlayer connection conductor 23g overlapping the second conductor layer 22d when viewed in the thickness direction of the third resin layer 13c is located at the third resin layer 13c. The interlayer connection conductor 23h is located at the third resin layer 13c. In addition, the second conductor layers 22g and 22h overlapping the interlayer connection conductors 23g and 23h are located at the third resin layer 13c.

The second conductor layers 22b, 22e, and 22f and the interlayer connection conductors 23e and 23f overlap the first conductor layer 21b when viewed in the thickness direction of the third resin layer.

The second resin layer 12 includes a thermoplastic resin, and the melting point of the second resin layer 12 is lower than the melting point of the first resin layer 11. More specifically, when named in view of the difference in melting point, the first resin layer 11 is a high-melting-point resin, and the second resin layer 12 is a low-melting-point resin.

The melting point of the second resin layer 12 is lower than a thermal pressing temperature, and the melting point of the first resin layer 11 is higher than the thermal pressing temperature. Thus, during thermal pressing, the second resin layer 12 becomes flexible earlier than the first resin layer 11, and air bubbles in the second resin layer 12 are filled with the second resin, and the coplanarity of the outer surface of the first resin layer 11 can be effectively enhanced.

The second resin layer 12 includes a porous material having a large number of air bubbles Fo. When the pressure applied in the thickness direction of the second resin layer 12 has a partial difference during thermal pressing, the amount by which the second resin layer 12 is recessed varies in accordance with the pressure. More specifically, the second resin layer 12 is recessed more deeply at a portion applied with a higher pressure. Thus, the second resin layer 12 may also be referred to as a buffer layer (a layer with cushioning properties), a pressure absorbing layer, or an irregularity absorbing layer.

The first resin layer 11 including a high-melting-point resin is pressed while retaining high rigidity during thermal pressing.

The first resin layer 11, the second resin layer 12, and the third resin layers 13a, 13b, and 13c at which the conductor layers and the interlayer connection conductors illustrated in FIG. 1 are located are laminated, and thermally pressed with a pressing member having a flat surface. More specifically, a pressing member presses and heats a laminated body in which the first resin layer 11, the second resin layer 12, and the third resin layers 13a, 13b, and 13c are laminated.

FIG. 2 is a cross-sectional view of the resin laminated board 1 formed by laminating the resin layers illustrated in FIG. 1, and thermally pressing the resin layers with the pressing member. Unlike the first resin layer 11 defining and functioning as an outermost layer, the second resin layer 12 defining and functioning as an inner layer is a low-melting-point resin layer, and a resin layer including a thermoplastic porous material. Thus, when the laminated body including multiple resin layers is thermally pressed, the resin laminated board 1 has high coplanarity at the first resin layer defining and functioning as an outermost layer. According to the present example embodiment, the first conductor layer 21b located at the first resin layer 11 or the outermost layer has improved coplanarity.

With this thermal pressing, the third resin layers 13a, 13b, and 13c illustrated in FIG. 1 are integrated into a third resin layer 13. The second conductor layers 22g and 22h located at the upper surface of the third resin layer 13c are embedded along the upper surface of the third resin layer 13. Thus, the upper surface of the resin laminated board 1 is flattened.

In an integrated laminated board including multiple thermoplastic resin layer sheets, the coplanarity of the top layer is lowered during pressing due to, for example, the density distribution of the inner-layer conductor.

In contrast, according to the present example embodiment, regardless of when the thickness varies between portions due to the difference in density of the inner-layer conductor, low-melting-point resin absorbs irregularities during thermal pressing, and the (equal) pressure can be applied to each interlayer connection conductor while maintaining the coplanarity of the top layer. Thus, the stress exerted on the outermost-layer conductor pattern has less unevenness, and the outermost-layer conductor pattern has improved coplanarity. The melting point of the outermost first resin layer 11 is higher than the melting point of the resin of the inner-layer second resin layer 12. The third resin layer including a resin with a relatively higher melting point thus maintains its rigidity during thermal pressing, a positional shift or subduction (submergence) of the outermost-layer conductor pattern is reduced, and the outermost-layer conductor pattern has improved coplanarity.

According to the present example embodiment, no conductor layer is located between the first resin layer 11 and the second resin layer 12, and air in the air bubbles in the first resin layer 11 is more likely to flow into the air bubbles in the second resin layer 12. Thus, the second resin layer 12 is easily deformed by the pressure, and the coplanarity of the outer surface of the first resin layer 11 is maintained.

According to the present example embodiment, the second resin layer 12 including a low-melting-point resin is a thermoplastic resin. Thus, the second resin layer 12 is not cured during thermal pressing, and highly efficiently flows into the air bubbles, and the coplanarity of the outer surface of the first resin layer 11 is thus maintained.

According to the present example embodiment, resin flows into the air bubbles in the second resin layer during thermal pressing while leaving some of the air bubbles unoccupied (leaving some air bubbles open). The ratio of the air bubbles (or a rate of air bubbles in a resin, or may be called “unoccupied efficiency”) is at such a high level as described above, and thus, the outermost-layer conductor pattern has improved coplanarity corresponding to a large difference in distribution density of the conductor layer.

Preferably, the air bubble ratio of the second resin layer 12 approximates the air bubble ratio of the first resin layer 11 as a result of the air bubbles in the second resin layer 12 being filled (air bubbles being occupied by resin). The strength of the second resin layer is thus maintained at a high level, and the rigidity of the entire resin laminated board is enhanced.

The thermal pressing described above may be performed either under the atmospheric pressure or in a vacuum.

When the first resin layer 11 and the second resin layer 12 are bonded, due to thermal pressing, the first resin layer 11 and the second resin layer 12 may react and the distribution of the air bubble ratio may be inclined. Such a structure is also included in the range of the structures of example embodiments of the present invention where the upper main surface of the first resin layer and the lower main surface of the second resin layer are in contact.

Non-limiting examples of a method for forming a porous resin layer are described as below. (a) Compressed gas is mixed into a heated resin to form air bubbles. (b) A foaming agent is mixed into the resin, and the mixture is heated to allow the foaming agent to foam to form air bubbles. (c) A solvent is mixed into the resin, and the mixture is heated to evaporate the foaming agent to form air bubbles.

FIG. 3 is a cross-sectional view of a resin laminated board 1A according to the first example embodiment, different from the resin laminated board illustrated in FIG. 2. The resin laminated board 1A is obtained by disposing a protection film 3a at the lower surface of the resin laminated board 1 illustrated in FIG. 2 and disposing a protection film 3b at the upper surface of the resin laminated board 1. The structure of the resin laminated board 1 in FIG. 3 is the same as that illustrated in FIG. 2.

The protection films 3a and 3b are located by, for example, applying solder resist. Alternatively, the protection films 3a and 3b are located by bonding cover lay layers including polyimide (PI).

By thus disposing the protection films 3a and 3b at the upper and lower surfaces of the resin laminated board 1, the conductor layers exposed at the outer surfaces can be protected.

Although FIG. 1, FIG. 2, and FIG. 3 illustrate a single resin laminated board, when multiple resin laminated boards are to be manufactured concurrently, a resin laminated board illustrated in FIG. 1, FIG. 2, and FIG. 3 that continuously extends by a distance corresponding to multiple laminated boards may be laminated, thermally pressed, and then divided into individual (separate) resin laminated boards.

In FIG. 2 and FIG. 3, for example, the conductor layer 22b is a signal conductor of a transmission line, and the conductor layer 21b is an opposite ground conductor layer. The conductor layer 21b, the conductor layer 22b, and portions of the first resin layer 11, the second resin layer 12, and the third resin layer 13 between the conductor layer 21b and the conductor layer 22b define a microstrip line. The conductor layers 22e and 22f and the interlayer connection conductors 23e and 23f function as signal lines for the conductor layer 22b defining and functioning as a signal conductor.

According to the present example embodiment, the resin laminated board has improved coplanarity. Thus, the variation in thickness of the resin layers located above and below the transmission line is reduced, and the variation of characteristic impedance of the transmission line is thus reduced.

Although a resin laminated board including a transmission line is described in the present example embodiment, the present invention is not limited to this example, and is applicable to a substrate including various conductor layers. For example, a resin laminated board having an antenna function including a radiating element located at the first resin layer 11 is described below.

A resin laminated board according to a second example embodiment described below differs from the resin laminated board according to the first example embodiment in the structures of the first resin layer 11 and the second resin layer 12.

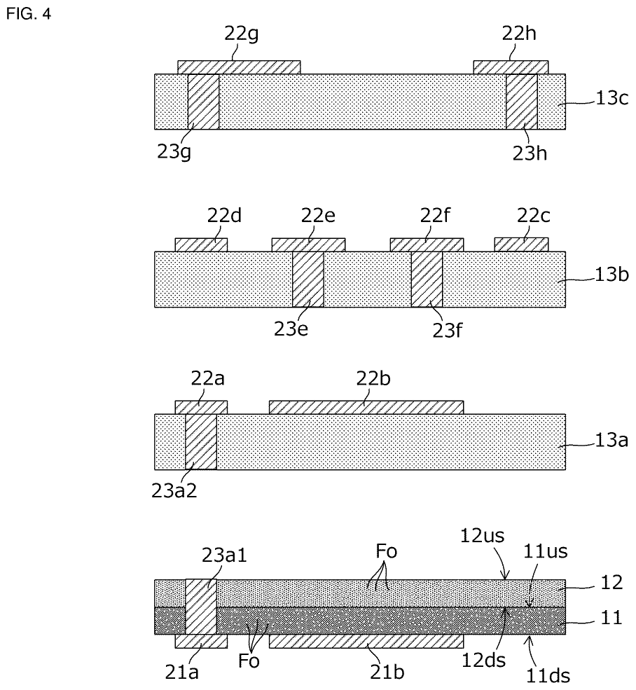

FIG. 4 is a cross-sectional view of a structure of each resin layer defining a portion of a resin laminated board according to a second example embodiment. As described in the first example embodiment, the second resin layer 12 includes a porous material having a large number of air bubbles Fo. In the second example embodiment, the first resin layer 11 also includes a porous material having a large number of air bubbles Fo. However, the second resin layer 12 including a low-melting-point resin has a greater air bubble ratio than the first resin layer 11 including a resin having a relatively higher melting point. Thus, when the pressure applied in the thickness direction of the first resin layer 11 and the second resin layer 12 has a partial difference, the amount by which the first resin layer 11 is recessed together with the second resin layer 12 varies in accordance with the pressure. More specifically, the second resin layer 12 is recessed more deeply at a portion applied with a higher pressure. Thus, both the first resin layer 11 and the second resin layer 12 may also be referred to as buffer layers (layers with cushioning properties), pressure absorbing layers, or irregularity absorbing layers.

According to the present example embodiment, during thermal pressing, the first resin layer 11 also includes air bubbles into which the resin flows, and thus the molten resin has many routes to escape. Thus, when the air-bubble ratio of the second resin layer 12 including a deformable low-melting-point resin is raised, these air bubbles are more likely to be occupied. As in the case of the first example embodiment, the first resin layer 11 including a high-melting-point resin is pressed while maintaining its high rigidity during thermal pressing, as compared with the second resin layer. Thus, the improvement of coplanarity of the outer surface of the first resin layer 11 can be expected. When the air-bubble ratio of the second resin layer 12 is comparatively (relatively) raised, the dielectric constant of the second resin layer 12 can be lowered. This structure can thus have intended characteristic impedance regardless of when the line width is increased. Thus, transmission loss at the signal transmission path can be reduced.

In a third example embodiment, deformation (uneven form) inside the third resin layer in the cross-sectional direction of the conductor layer is described as an example. In the third example embodiment, a resin laminated board having an outer surface on which an electronic component is mounted is described as an example.

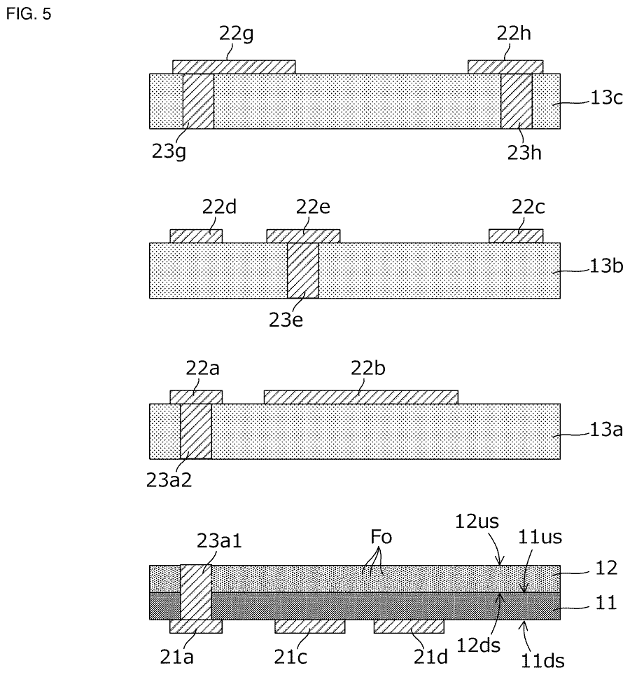

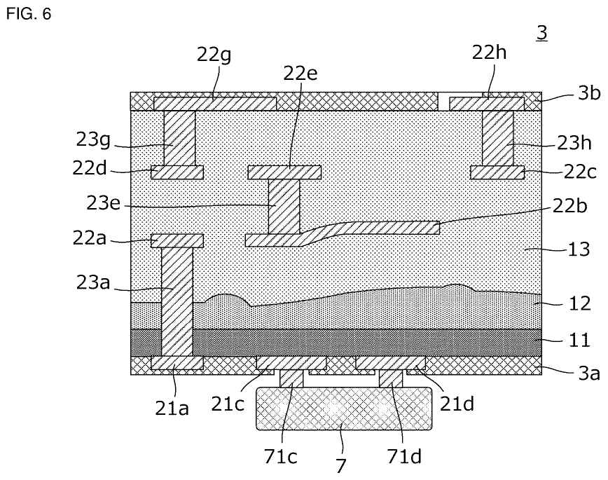

FIG. 5 is a cross-sectional view of a structure of each resin layer included in a portion of a resin laminated board according to a third example embodiment. FIG. 6 is a cross-sectional view of a resin laminated board 3 formed by thermal pressing.

A resin laminated board 1 includes multiple resin layers laminated on one another, and conductors located outside and inside the laminated multiple resin layers. In FIG. 5 and FIG. 6, a first resin layer 11, a second resin layer 12, and third resin layers 13a, 13b, and 13c correspond to “resin layers” described above. First conductor layers 21a, 21c, and 21d, second conductor layers 22a to 22h, and interlayer connection conductors 23a1, 23a2, 23e, 23g, and 23h correspond to “conductors” described above.

As illustrated in FIG. 5, the first resin layer 11 has an upper main surface 11us and a lower main surface 11ds opposite to each other. The second resin layer 12 has an upper main surface 12us and a lower main surface 12ds opposite to each other.

The upper main surface 11us of the first resin layer 11 is in contact with the lower main surface 12ds of the second resin layer 12.

The first conductor layers 21a, 21c, and 21d are located at the lower main surface 11ds of the first resin layer 11.

The interlayer connection conductor 23a2 and the second conductor layer 22a that overlap the first conductor layer 21a when viewed in the thickness direction of the third resin layer 13a are located at the third resin layer 13a. The second conductor layer 22b is also located at the third resin layer 13a.

The interlayer connection conductor 23e that overlaps the second conductor layer 22b when viewed in the thickness direction of the third resin layer 13b is located at the third resin layer 13b. The second conductor layer 22e that overlaps the interlayer connection conductor 23e is also located at the third resin layer 13b. The second conductor layers 22c and 22d are located at the third resin layer 13b.

The interlayer connection conductor 23g that overlaps the second conductor layer 22d when viewed in the thickness direction of the third resin layer 13c is located at the third resin layer 13c. The interlayer connection conductor 23h is located at the third resin layer 13c. The second conductor layers 22g and 22h that overlap the interlayer connection conductors 23g and 23h are located at the third resin layer 13c.

The second resin layer 12 is a thermoplastic resin, and the melting point of the second resin layer 12 is lower than the melting point of the first resin layer 11. More specifically, when named in view of the difference in melting point, the first resin layer 11 is a high-melting-point resin, and the second resin layer 12 is a low-melting-point resin.

The second resin layer 12 includes a porous material including a large number of air bubbles Fo. Thus, when the pressure applied in the thickness direction of the second resin layer 12 has a partial difference during thermal pressing, the amount by which the second resin layer 12 is recessed varies in accordance with the pressure. More specifically, the second resin layer 12 is recessed more deeply at a portion applied with a higher pressure. Thus, the second resin layer 12 may also be referred to as a buffer layer (a layer with cushioning properties), a pressure absorbing layer, or an irregularity absorbing layer.

The first resin layer 11 including a high-melting-point resin is pressed while retaining high rigidity during thermal pressing, as compared with the second resin layer.

The first resin layer 11, the second resin layer 12, and the third resin layers 13a, 13b, and 13c at which the conductor layers and the interlayer connection conductors illustrated in FIG. 5 are formed are laminated, and thermally pressed with a rigid structure having a flat surface.

FIG. 6 is a cross-sectional view of the resin laminated board 3 formed by laminating the resin layers illustrated in FIG. 5, disposing a protection film 3a at the lower surface of the resin laminated board formed by thermally pressing the laminated resin layers with the rigid structure, and disposing a protection film 3b at the upper surface of the resin laminated board. Unlike the first resin layer 11 defining and functioning as an outermost layer, the second resin layer 12 defining and functioning as an inner layer is a low-melting-point resin layer, and a resin layer including a thermoplastic porous material. Thus, when the laminated body including multiple resin layers is thermally pressed, the resin laminated board 3 has high coplanarity at the first resin layer 11 defining and functioning as an outermost layer and the first conductor layers 21c and 21d, although the conductor layer 22b is deformed in accordance with upward pressing from the conductor layers 21c and 21d.

Terminals 71c and 71d of an electronic component 7 are mounted at the first conductor layers 21c and 21d by, for example, being soldered. Regardless of when an electronic component is mounted at the outer surface of the resin laminated board 3 as in the present example embodiment, the electronic component 7 is easily and reliably mounted at the first conductor layers 21c and 21d having high coplanarity.

In the fourth example embodiment, a resin laminated board in which an electronic component is mounted is described as an example.

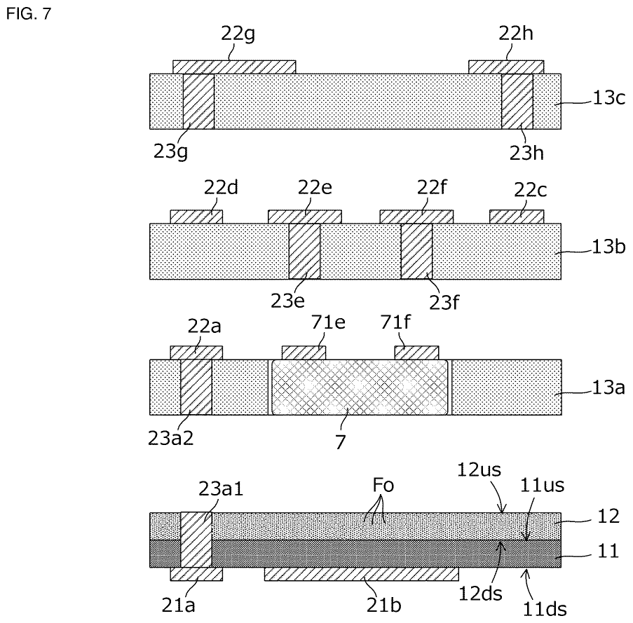

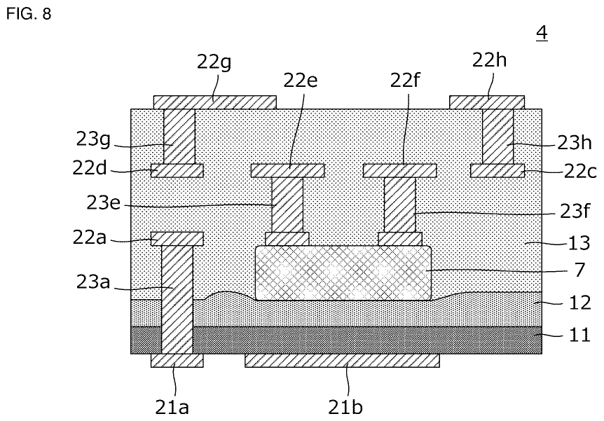

FIG. 7 is a cross-sectional view of a structure of each resin layer forming a portion of a resin laminated board according to a fourth example embodiment. FIG. 8 is a cross-sectional view of the resin laminated board 4 formed by laminating the resin layers illustrated in FIG. 7, and by thermally pressing the resin layers with a rigid structure.

The resin laminated board 4 includes multiple resin layers laminated on one another, and conductors located outside and inside the laminated multiple resin layers. In FIG. 7 and FIG. 8, a first resin layer 11, a second resin layer 12, and third resin layers 13a, 13b, and 13c correspond to the “resin layers” described above. First conductor layers 21a and 21b, second conductor layers 22a, and 22c to 22h, and interlayer connection conductors 23a1, 23a2, 23e, 23f, 23g, and 23h correspond to the “conductors” described above.

The first conductor layers 21a and 21b are located at the lower main surface of the first resin layer 11.

The third resin layer 13a has a through hole for receiving (or embedding) the electronic component 7, and the electronic component 7 is inserted into the through hole. Terminals 71e and 71f of the electronic component 7 are in contact with the interlayer connection conductors 23e and 23f. The first conductor layer 21b is located at the first resin layer 11 at a position where the electronic component overlaps the electronic component 7 when viewed in the thickness direction of the first resin layer 11. The electronic component 7 is a component such as an integrated circuit (IC), a chip capacitor, or a chip inductor.

The first conductor layer 21b in the resin laminated board 4 according to the present example embodiment can maintain high coplanarity during thermal pressing. Generally, a resin laminated board in which an electronic component is built has low coplanarity at the outer surface. However, the second resin layer 12 including a low-melting-point resin layer included in the resin laminated board improves coplanarity of the outer surface of the resin laminated board.

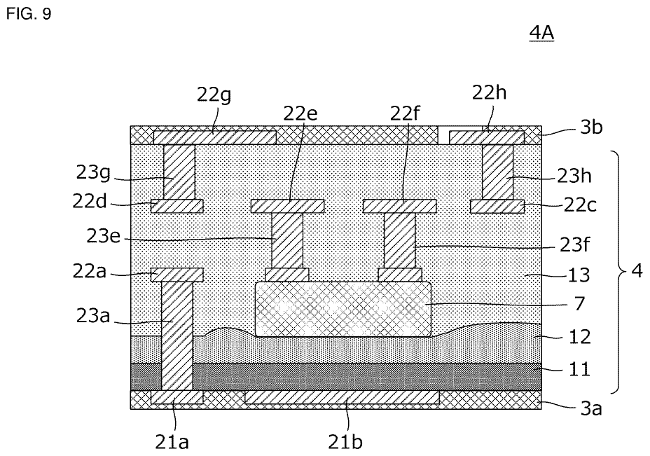

FIG. 9 is a cross-sectional view of the resin laminated board 4A according to the fourth example embodiment, different from the resin laminated board 4 illustrated in FIG. 8. The resin laminated board 4A is obtained by providing a protection film 3a at the lower surface of the resin laminated board 4 illustrated in FIG. 8 and disposing a protection film 3b at the upper surface of the resin laminated board 4. The structure of the resin laminated board 4 in FIG. 9 is the same as that illustrated in FIG. 8.

Protecting the protection films 3a and 3b at the upper and lower surfaces of the resin laminated board 4 in this manner can protect conductor layers exposed to the outer surfaces.

In the fifth example embodiment, a resin laminated board including an antenna is described as an example.

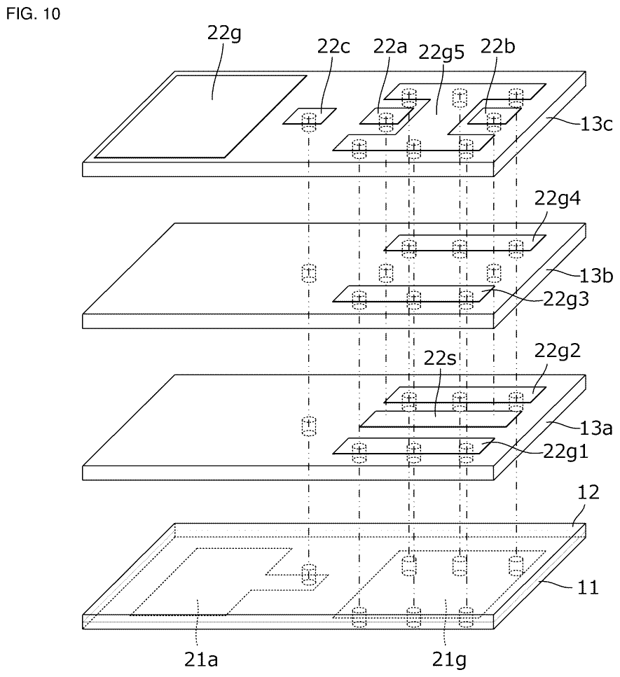

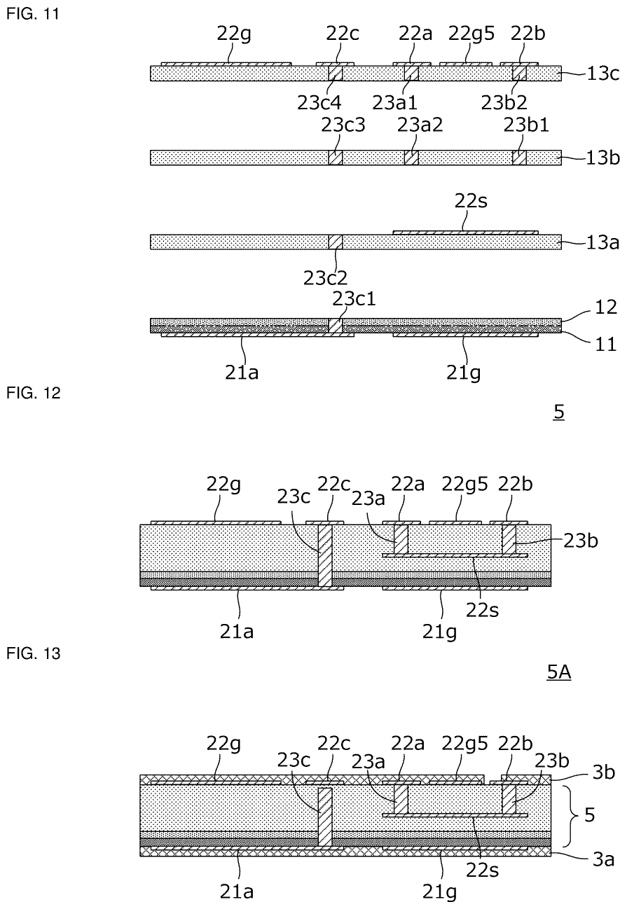

FIG. 10 is a perspective view of a structure of each resin layer forming a portion of a resin laminated board according to a fifth example embodiment. FIG. 11 is a cross-sectional view of a structure of each resin layer forming a portion of the resin laminated board according to the fifth example embodiment. FIG. 12 is a cross-sectional view of a resin laminated board 5 formed by laminating the resin layers illustrated in FIG. 11, and thermally pressing the laminated resin layers with a rigid structure.

The resin laminated board 1 includes multiple resin layers laminated on one another and conductors located outside and inside the laminated multiple resin layers. In FIG. 10 and FIG. 11, a first resin layer 11, a second resin layer 12, and third resin layers 13a, 13b, and 13c correspond to “resin layers” described above. In addition, first conductor layers 21a and 21g, second conductor layers 22g1, 22g2, 22g3, 22g4, 22g5, 22g, 22s, 22a, 22b, 22c, and 22s, and interlayer connection conductors 23a1, 23a2, 23b1, 23b2, 23c1, 23c2, 23c3, and 23c4, and other components correspond to “conductors” described above.

The second resin layer 12 is a thermoplastic resin, and the melting point of the second resin layer 12 is lower than the melting point of the first resin layer 11. More specifically, when named in view of the difference in melting point, the first resin layer 11 is a high-melting-point resin, and the second resin layer 12 is a low-melting-point resin.

The second resin layer 12 is a porous material having a large number of air bubbles Fo. Thus, when the pressure applied in the thickness direction of the second resin layer 12 has a partial difference during thermal pressing, the amount by which the second resin layer 12 is recessed varies in accordance with the pressure.

The first resin layer 11 including a high-melting-point resin is pressed while retaining high rigidity during thermal pressing, as compared with the second resin layer.

The first conductor layer 21a is a radiating element, and the second conductor layer 22g is an opposite ground layer opposite to the first conductor layer 21a. The first conductor layer 21a is electrically connected to the second conductor layer 22c through the interlayer connection conductors 23c1, 23c2, 23c3, and 23c4. The first conductor layer 21a, the second conductor layers 22g and 22c, and the interlayer connection conductors 23c1, 23c2, 23c3, and 23c4 define a patch antenna.

The second conductor layer 22s is a signal conductor, and the second conductor layers 22a and 22b are electrically connected to the second conductor layer 22s through the interlayer connection conductors 23a1, 23a2, 23b1, and 23b2. These second conductor layers 22s, 22a, and 22b and the interlayer connection conductors 23a1, 23a2, 23b1, and 23b2 define a microstrip line or a strip line. The second conductor layers 22g1, 22g2, 22g3, 22g4, and 22g5 and interlayer connection conductors that electrically connect these second conductor layers 22g1, 22g2, 22g3, 22g4, and 22g5 in the layer direction have a ground potential, and function as a shield electrode that shields the microstrip.

The first resin layer 11 with a high melting point, or the outermost layer at which the conductor layer 21a defining and functioning as a radiating element is located has a higher dielectric constant than the second resin layer 12 including a large number of pores and defining and functioning as an inner layer. Thus, the first resin layer 11 having a high dielectric constant around the first conductor layer 21a defining and functioning as a radiating element enables size reduction of an antenna with a wavelength compression effect.

In contrast, the dielectric constant around the conductor layer 22s defining and functioning as a signal line is relatively low, and transmission loss caused by dielectric loss (Df) can be reduced.

FIG. 13 is a cross-sectional view of a resin laminated board 5A according to the fifth example embodiment, different from the resin laminated board illustrated in FIG. 12. The resin laminated board 5A is obtained by disposing a protection film 3a at the lower surface of the resin laminated board 1 illustrated in FIG. 12 and disposing a protection film 3ba at the upper surface of the resin laminated board 1. The structure of the resin laminated board 5 in FIG. 13 is the same as that illustrated in FIG. 12.

In the resin laminated board according to the present example embodiment, the variation in distance between the first conductor layer 21a defining and functioning as a radiating element and the second conductor layer 22g defining and functioning as an opposite ground conductor layer is reduced, and the variation in resonance frequency of an antenna is reduced. The resin laminated board has the above effects regardless of when including a second conductor layer defining and functioning as a radiating element located near the second resin layer and a first conductor layer defining and functioning as an opposite ground conductor layer located near the first resin layer.

In each of the example embodiments described above, a conductor layer including, for example, copper foil is located simply at a single surface of each resin layer before the lamination resulting from thermal pressing is performed. However, a conductor layer may be partially or entirely formed over each of both surfaces of an intended resin layer.

In each of the example embodiments described above, multiple resin layers include a first resin layer, a second resin layer, and a third resin layer sequentially laminated on one another, and the first resin layer and the third resin layer serve as outermost surfaces of a resin laminated board. However, a pair of the first resin layer and the second resin layer may be located at each of both surfaces of a resin laminated board. More specifically, for example, “the first resin layer”, “the second resin layer”, “the third resin layer”, “the second resin layer”, and “the first resin layer” may be laminated in this order, and thermally pressed to form a resin laminated board.

Finally, the present invention is not limited to the example embodiments described above. Modifications and alterations can be made by those skilled in the art as appropriate. The scope of the present invention is defined not by the above example embodiments but by the claims. The scope of the present invention also includes modifications and alterations from the example embodiments within the scope equivalent to that of the claims.

While example embodiments of the present invention have been described above, it is to be understood that variations and modifications will be apparent to those skilled in the art without departing from the scope and spirit of the present invention. The scope of the present invention, therefore, is to be determined solely by the following claims.

What is claimed is:

1. A resin laminated board, comprising:
a plurality of resin layers laminated on one another; and
conductors located outside and inside the laminated plurality of resin layers; wherein
the plurality of resin layers include a first resin layer, a second resin layer, and a third resin layer sequentially laminated on one another;
the conductors include a first conductor layer, a second conductor layer, and an interlayer connection conductor;
the first resin layer includes an upper main surface and a lower main surface opposite to each other;
the second resin layer includes an upper main surface and a lower main surface opposite to each other;
the upper main surface of the first resin layer is in contact with the lower main surface of the second resin layer;
the first conductor layer is located at the lower main surface of the first resin layer;
the second conductor layer or the interlayer connection conductor that overlaps a portion of the first conductor layer when viewed in a thickness direction of the third resin layer is located at the third resin layer;
the second resin layer is a thermoplastic resin, and a melting point of the second resin layer is lower than a melting point of the first resin layer; and
at least the second resin layer includes air bubbles.

2. The resin laminated board according to claim 1, wherein an air bubble ratio of the second resin layer is higher than an air bubble ratio of the first resin layer.

3. The resin laminated board according to claim 1, wherein
the first resin layer and the second resin layer are in direct contact with each other; and
no conductor layer is located between the first resin layer and the second resin layer.

4. The resin laminated board according to claim 1, wherein
the second conductor layer that overlaps at least a portion of the first conductor layer when viewed in the thickness direction of the third resin layer is located at the third resin layer; and
at least a portion of the first conductor layer defines and functions as a radiating element, and the second conductor layer that overlaps at least a portion of the first conductor layer defines and functions as a ground conductor; or
at least a portion of the second conductor layer defines and functions as a radiating element, and the first conductor layer that overlaps at least a portion of the second conductor layer defines and functions as a ground conductor.

5. The resin laminated board according to claim 4, wherein the radiating element is located at the first resin layer, and a dielectric constant of the first resin layer is higher than a dielectric constant of the second resin layer, or the radiating element is located at the third resin layer, and a dielectric constant of the third resin layer is higher than a dielectric constant of the first resin layer.

6. The resin laminated board according to claim 1, wherein a protection film is located at an outer surface of a laminated body including the plurality of resin layers laminated on one another and the conductors located outside and inside the laminated plurality of resin layers.

7. The resin laminated board according to claim 1, wherein an electronic component is located in the third resin layer at a position where the electronic component overlaps the first conductor layer.

8. The resin laminated board according to claim 1, wherein the lower main surface of the first resin layer is an outermost layer of a laminated body including the plurality of resin layers laminated on one another and the conductors located outside and inside the laminated plurality of resin layers, and a portion of the first conductor layer is located at the lower main surface of the first resin layer.

9. The resin laminated board according to claim 1, wherein the first resin layer, the second resin layer, and the third resin layer have different melting points from each other.

10. The resin laminated board according to claim 1, wherein the first resin layer, the second resin layer, and the third resin layer include at least one of liquid crystal polymer, polytetrafluoroethylene, or polyimide.

11. The resin laminated board according to claim 1, wherein the melting point of the second resin layer is lower than a thermal pressing temperature of the resin laminated board.

12. The resin laminated board according to claim 1, wherein the melting point of the first resin layer is higher than a thermal pressing temperature of the resin laminated board.

13. The resin laminated board according to claim 1, wherein the second resin layer is a buffer layer, a pressure absorbing layer, or an irregularity absorbing layer.

14. The resin laminated board according to claim 1, wherein the second conductor layer is embedded along an upper surface of the third resin layer.

15. The resin laminated board according to claim 1, wherein a melting pint of the third resin layer is higher than the melting point of the first resin layer or the second resin layer.

16. The resin laminated board according to claim 2, wherein a distribution of the air bubble ratio is inclinded.

17. The resin laminated board according to claim 1, wherein the first or second signal conductor defines a transmission line, and the second or first signal conductor defines a ground conductor layer.

18. The resin laminated board according to claim 1, wherein the first conductor layer, the second signal conductor, and portions of the first resin layer, the second resin layer, and the third resin layer define a microstrip line.

19. The resin laminated board according to claim 1, further comprising an antenna.

20. A method for manufacturing a resin laminated board including a plurality of resin layers laminated on one another and conductors located outside and inside the laminated plurality of resin layers, the plurality of resin layers including a first resin layer, a second resin layer, and a third resin layer sequentially laminated on one another, the conductors including a first conductor layer, a second conductor layer, and an interlayer connection conductor, the first resin layer including an upper main surface and a lower main surface opposite to each other, the second resin layer including an upper main surface and a lower main surface opposite to each other, the upper main surface of the first resin layer being in contact with the lower main surface of the second resin layer, the first conductor layer being located at the lower main surface of the first resin layer, the second conductor layer or the interlayer connection conductor that overlaps a portion of the first conductor layer when viewed in a thickness direction of the third resin layer being located at the third resin layer, the second resin layer being a thermoplastic resin including air bubbles inside before being subjected to thermal pressing, and a melting point of the second resin layer being lower than a melting point of the first resin layer, the method comprising:
performing thermal pressing on the first resin layer, the second resin layer, and the third resin layer that are laminated on one another, at a temperature lower than the melting point of the first resin layer and higher than the melting point of the second resin layer.
